(19) United States
(12) Patent Application Publication
(10) Pub. No.: US 2014/0356637 A1
(43) Pub. Date: Dec. 4, 2014

(54) METHOD OF MANUFACTURING A CERAMIC ELECTRONIC COMPONENT

(71) Applicant: E I DU PONT DE NEMOURS AND COMPANY, Wilmington, DE (US)

(72) Inventor: JI-YEON LEE, KANAKAWA-KEN (KR)

(73) Assignee: E I DU PONT DE NEMOURS AND COMPANY, Wilmington, DE (US)

(21) Appl. No.: 14/280,739

(22) Filed: May 19, 2014

Related U.S. Application Data
(60) Provisional application No. 61/828,210, filed on May 29, 2013.

(51) Int. Cl. G03F 7/40

(52) U.S. Cl. CPC G03F 7/40
USPC 428/446; 430/311

(57) ABSTRACT

A method of manufacturing a ceramic electronic component, comprising steps of: (i) forming an polymer layer on at least one side of a ceramic green sheet; (ii) forming a thick-film layer by applying a photosensitive paste on the polymer layer; (iii) exposing the thick-film layer to light; (iv) developing the thick-film layer; and (v) heating the ceramic green sheet and the thick-film layer.

### FIELD OF THE INVENTION

This invention relates to a ceramic electrical component, more specifically a method of manufacturing a ceramic electrical component by a photolithographic technique.

### BACKGROUND OF THE INVENTION

A ceramic electrical component is formed with a ceramic green sheet and a thick-film layer.

US20070235694 discloses a method of making a multilayer circuit with ceramic green sheets. The method comprises printing a conductive paste in a circuit pattern on the green sheet, laminating the green sheets to form an assemblage, and heating the assemblage.

### SUMMARY OF THE INVENTION

An objective is to provide a method of manufacturing a ceramic electrical component by using a thick-film layer and a photolithographic technique. The photolithographic approach is especially useful to form a fine functional pattern such as an electrode circuit, resistor and dielectric.

An aspect of the present invention is a method of manufacturing a ceramic electronic component, comprising steps of: (i) forming an polymer layer on at least one side of a ceramic green sheet; (ii) forming a thick-film layer by applying a photosensitive paste on the polymer layer; (iii) exposing the thick-film layer to light; (iv) developing the thick-film layer; and (v) heating the ceramic green sheet and the thick-film layer.

Another aspect of the invention relates to a ceramic green sheet, wherein a polymer layer is formed on one side of the ceramic green sheet.

The ceramic electrical component with fine pattern can be formed by the present invention.

### BRIEF DESCRIPTION OF THE DRAWINGS

FIGS. 1A to 1G explain the photolithographic method of manufacturing a ceramic electrical component.

FIG. 2 is a cross sectional diagram of a multilayer ceramic electronic component.

FIG. 3 shows a circuit pattern formed in Example 1.

FIG. 4 shows a circuit pattern formed in Example 2.

FIG. 5 shows a circuit pattern formed in Example 3.

FIG. 6 shows a circuit pattern formed in Comparative Example 1.

### DETAILED DESCRIPTION OF THE INVENTION

The photolithographic method of manufacturing a ceramic electrical component comprises at least steps of (i) forming an polymer layer on at least one side of a ceramic green sheet; (ii) forming a thick-film layer by applying a photosensitive paste on the polymer layer; (iii) exposing the thick-film layer to light; (iv) developing the thick-film layer; and (v) heating the ceramic green sheet and the thick-film layer. The thick-film layer can be developed with less residue by forming the polymer layer under the thick-film layer as shown in Example 1 below.

The polymer layer can be photosensitive or non-photosensitive. In the event of a photosensitive polymer layer, the photosensitive polymer layer can be independently exposed to light. In such embodiment, the method can further comprises a step of (i-a) exposing the polymer layer to light between the step (i) of forming an polymer layer and the step (ii) of forming the thick-film layer. In another embodiment, the photosensitive polymer layer can be exposed to light at the same time of exposing the thick-film layer. The thick-film layer can be developed with further less residue by forming the photosensitive polymer layer under the thick-film layer as shown in Example 2 and 3 below.

The ceramic electrical component can be a single-layer ceramic component or a multilayer ceramic electronic component that is formed by laminating the ceramic.

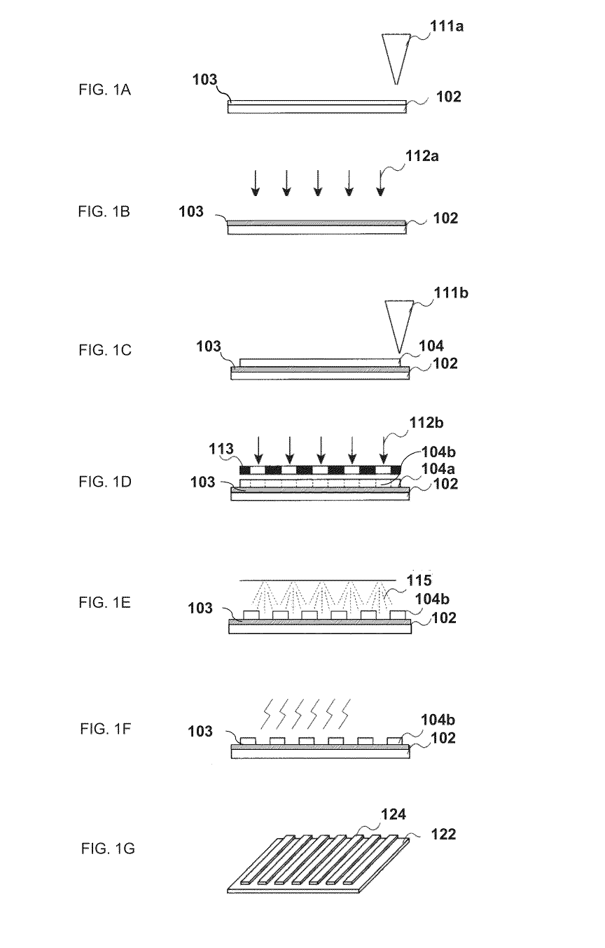

An example of the photolithographic method of manufacturing the multilayer ceramic electrical component in which the photosensitive polymer layer is independently exposed to light is explained along with FIGS. 1A to 1G.

(i) The polymer layer 103 is formed on a ceramic green sheet 102 with an applying tool 111a as illustrated in FIG. 1A. The polymer layer 103 is photosensitive in an embodiment.

The ceramic green sheet 102 is an unbaked ceramic sheet which is made from a slurry containing glass or inorganic oxide.

The ceramic green sheet can be a low temperature co-fired ceramic (LTCC) green sheet or a high temperature co-fired ceramic (HTCC) green sheet in another embodiment. The LTCC green sheet can be a rigid ceramic substrate by heating at lower than 1000° C. To the contrary, the HTCC green sheet can need 1000° C. or higher to get rigid.

The thickness of the ceramic green sheet is not limited. The thickness of the ceramic green sheet is adjustable by laminating two or more of single-layer of ceramic green sheet.

Any commercially available green sheet such as Green Tape®. from E.I. DuPont de Nemours and Company can be used as the ceramic green sheet.

The polymer layer 103 can be formed on at least one side of the ceramic green sheet 102. The polymer layer 103 can be formed on both side of the green sheet 102 in another embodiment especially when the thick-film layers are formed on both sides of the ceramic green sheet 102.

It can be sufficient to form the polymer layer 103 on at least area where the thick-film layer is formed. In an embodiment, the polymer layer 103 can be formed on the entire surface of the ceramic green sheet 102 in order to make sure the polymer layer 103 lies under the thick-film layer.

The polymer layer 103 thickness can vary depending on the thickness of the ceramic green sheet 102 or the thick-film layer. The polymer layer 103 thickness is 0.1 to 100 μm in an embodiment, 0.5 to 50 μm in another embodiment, 1 to 10 μm in another embodiment.

The polymer layer 103 can be formed by applying a polymer paste or a polymer film in an embodiment.

In another embodiment, the polymer layer 103 is formed by applying the polymer paste. The polymer paste is a viscous composition containing at least a polymer.

The way of applying the polymer paste on the ceramic green sheet 102 can be screen printing, inkjet printing, gravure printing, stencil printing, spin coating, blade coating, nozzle coating, spray coating, or dipping in an embodiment. The screen printing, spin coating and blade coating which are relatively simple and easy to apply a paste can be selected in another embodiment. In another embodiment, the ceramic green sheet can be partially or entirely dipped into a container filled with the polymer paste. The polymer layer can be formed on the entire surface of the ceramic green sheet when the ceramic green sheet is wholly dipped into the container.

In an embodiment, the polymer layer 103 can be formed by applying a polymer film. The polymer film can be made by applying the polymer paste on a support film such as a polyethylene terephthalate film and drying the polymer paste on the support film. The support film is peeled off and the dried polymer paste as a polymer film can be put on the ceramic green sheet 102.

The polymer layer 103 on the ceramic green sheet 102 can be dried in an embodiment. The drying condition can be 50 to 250° C. for 1 to 60 minutes in an oven or a dryer in another embodiment.

The polymer layer 103 can be photosensitive with negative tone by using a polymer paste containing a photopolyrnerizable compound in another embodiment. When the polymer layer 103 is photosensitive, the polymer layer 103 can be exposed to light 112a as illustrated in FIG. 1B. The light 112a can be ultraviolet light which has photo energy enough to cure the polymer layer 103 in another embodiment.

The photosensitive polymer layer 103 can be cured at least area where the thick-film layer is formed afterward. To be entirely cured, the polymer layer 103 can be entirely exposed to the light in an embodiment. In another embodiment, the polymer layer 103 can be partially exposed to the light 112a for example by irradiating the light 112a through a photo mask having a pattern.

The exposing condition can be controlled according to photosensitivity and thickness of the polymer layer 103. The cumulative exposure can be 5 to 2000 mJ/² in an embodiment, 50 to 1000 mJ/cm² in another embodiment.

The polymer layer can consist of only polymer in an embodiment. In another embodiment, the polymer layer can comprise an additive such as an inorganic filler. The additive is 0.1 to 30 wt % in an embodiment, 1 to 20 wt % in another embodiment, and 3 to 10 wt % in another embodiment.

The polymer layer and the polymer paste composition are described in detail later.

In an embodiment, the ceramic green sheet with the polymer layer on at least one side of the ceramic green sheet can be produced in one place. The ceramic green sheet with the polymer layer can be stored in the production site and transfer to another place to complete forming the ceramic electric component.

The thick-film layer 104 is formed on the polymer layer 103 by applying a photosensitive paste with an applying tool 111b as illustrated in FIG. 1C.

The way of applying the photosensitive paste on the polymer layer 103 can be screen printing, inkjet printing, gravure printing, stencil printing, spin coating, blade coating or nozzle discharge in an embodiment. The screen printing, spin coating or blade coating which is relatively simple and easy to apply a paste can be taken in another embodiment.

The applying tool 111b to form a thick-film layer can be same as the applying tool 111a or can be different from the applying tool 111a to form the polymer layer 103.

The photosensitive paste can be a viscos composition that comprises at least a functional inorganic powder and an organic vehicle in an embodiment.

The functional inorganic powder can be selected from the group consisting of a metal powder, a metal oxide powder, and a glass powder in an embodiment.

In the event of a thick-film electrode circuit layer, the functional inorganic powder in the photosensitive paste can be a metal powder such as silver powder, copper powder, gold powder and aluminum powder.

In the event of a thick-film resistor layer, the functional inorganic powder in the photosensitive paste can be a metal oxide such as ruthenium oxide in another embodiment.

In the event of a thick-film dielectric layer or insulator, the photosensitive paste comprises at least a glass powder in another embodiment.

The photosensitive paste, both negative type and positive type can be used so that the organic vehicle is photosensitive with positive tone or negative tone.

For the photosensitive paste to form an electrode circuit, US20080012490, US20080011515 can be herein incorporated by reference. For the photosensitive paste to form a dielectric, US20060223690 and US20070224429 can be herein incorporated by reference. For the photosensitive paste to form a resistor, JP2006054495 can be herein incorporated by reference.

Any commercially available photosensitive paste can be used as the photosensitive paste, for example to form an electrode circuit, Fodel® from E. I. du Pont de Nemours and Company can be available.

The thick-film layer 104 can be dried in an embodiment although the drying step is not essential. The drying condition can be 50 to 250° C. for 1 to 30 minutes in an oven or a dryer. The thick film layer 104 after drying is 0.1 to 100 μm in an embodiment, 1 to 55 μm in another embodiment, 3 to 23 μm in another embodiment in view of making a fine pattern.

The thick-film layer 104 is exposed to light 112b as illustrated in FIG. 1D when the photosensitive paste is negative type. In the event of the negative type of photosensitive paste, the exposed area 104b of the thick-film layer harden to be unsoluble to an aqueous developer. The light 112b which has sufficient photo energy to cure the thick-film layer can be irradiated through a photo mask 113 which has a desired pattern so that the exposed area 104b of the thick-film layer can be cured. The light 112b can be ultraviolet light in an embodiment. The light 112b can be same as the light 112a exposed to the polymer layer 103 or different from the light 112a.

The exposing condition can be controlled according to photosensitivity of the photosensitive conductor paste and thickness of the thick-film layer 104. The cumulative exposure is 20 to 2000 mJ/cm² in an embodiment, 100 to 1000 mJ/cm² in another embodiment.

The thick-film layer 104 is developed with an aqueous solution 115 as illustrated in FIG. 1E The aqueous solution 115 is an alkaline solution such as a 0.4% sodium carbonate solution in an embodiment. The aqueous solution 115 can be sprayed to the thick film layer 104 to remove the unexposed area 104a. In an embodiment, the spraying condition of the alkaline solution 115 can be 0.1 to 0.4 MPa for 5 to 100 seconds. The pattern of the cured thick-film layer 104b appears by the development.

In the event of a positive type of photosensitive paste, the exposed area 104b becomes soluble to the aqueous solution 115 and the unexposed area 104a remains after the development.

The thick-film layer 104b and the ceramic green sheet 102 are heated as illustrated in FIG. 1F.

The term “heating” means heating the thick-film layer and the ceramic green sheet to volatilize the organic materials and/or sintering the inorganic components in the thick-film layer and the ceramic green sheet.

The heating can be carried out by using a furnace or an oven. The peak setting temperature can be 200 to 2500° C. in an embodiment, 400 to 2000° C. in another embodiment, and 500 to 1100° C. in another embodiment. Total heating time, for example from entrance to exit of the furnace, can be 1 to 20 hours in an embodiment, 2 to 15 hours in another embodiment.

The peak setting temperature can be 400 to 1500° C. in the event of using the LTCC green sheet in another embodiment. The peak setting temperature can be 1400 to 2500° C. in the event of using the HTCC green sheet in another embodiment.

The thick-film layer 104 becomes a functional pattern 124 such as electrode circuit, resistor and dielectric, and the ceramic green sheet 102 turns to a rigid ceramic substrate 122 as illustrated in FIG. 1G. The polymer layer 103 can burn out during the heating when the heating temperature is high enough for polymer gasification. However the polymer layer can remain as long as not giving any serious defect on the ceramic electrical component.

The functional pattern 124 can be of width 0.1 to 100 μm in an embodiment, 5 to 50 μm in another embodiment, 8 to 30 μm in another embodiment. The thickness of the pattern 124 can be 0.5 to 40 μm in an embodiment, 1 to 25 μm in another embodiment, 1.5 to 10 μm in another embodiment.

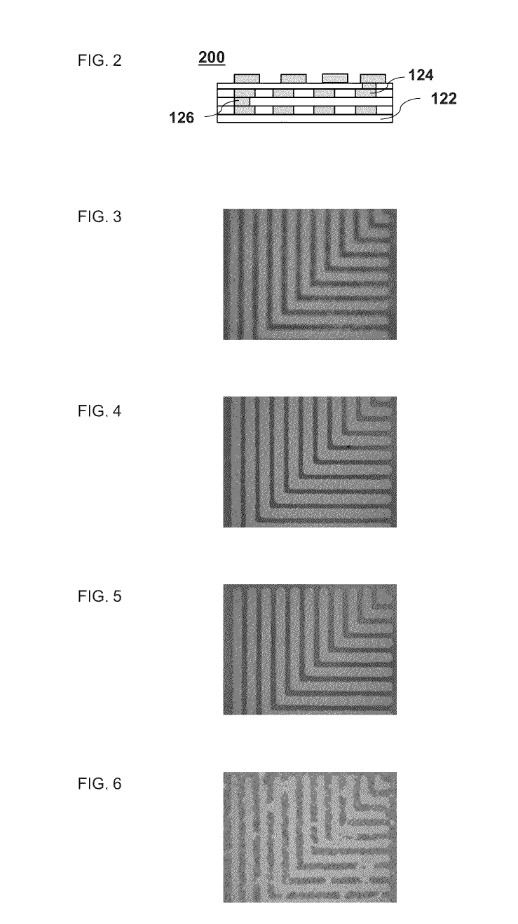

In another embodiment, the ceramic electrical component can be a multi-layered as shown in FIG. 2. The multilayer ceramic electronic component 200 comprises ceramic layers 122 and functional patterns 124 between the ceramic layers 122.

The multilayer ceramic electronic component 200 can comprise same or different functional patterns. For example, some of the functional patterns 124 are electrode circuits and the other functional patterns 124 are dielectrics.

When forming the multilayer ceramic electronic component 200, the method can further comprise a step of (iv-a) laminating at least two ceramic green sheets 102 with the developed thick-film layer 104b between the step (iv) of developing the thick-film layer and the step (v) of heating the thick-film layer.

The multilayer ceramic electronic component can contain a via hole 126 filled with a conductive material to electrically connect the functional pattern 124 such as electrode circuit between the ceramic layers 122 in an embodiment.

The multilayer ceramic electronic component can be MLCC (MultiLayer Ceramic Capacitor), MLI (MultiLayer Ceramic Inductor), or transient voltage suppressor, a multilayer ceramic substrate that can be used in RF (Radio Frequency) module and in IC (Integrated Circuit) package.

For the multilayer ceramic electronic component, US20070235694, US20070113952 and U.S. Pat. No. 5,293,025 can be herein incorporated by reference.

Next, the polymer paste to form the polymer layer is explained hereafter.

The polymer paste comprises at least a polymer to form a viscous composition having suitable viscosity for applying on a substrate.

The viscosity of the polymer paste can be 1 to 100 Pascal second (Pa·s) in an embodiment, 2 to 50 Pa·s in another embodiment. The viscosity can be measured with a viscometer DV-I™ Prime HAT from Brookfield Co., Ltd. using a spindle #14 at 10 rpm at room temperature.

To adjust the viscosity, a solvent can be added to the polymer. When mixing the polymer and solvent, the mixing weight ratio (polymer:solvent) can be 1:9 to 9:1 in an embodiment, 1:5 to 5:1 in another embodiment, 2:1 to 1:2 in another embodiment.

A wide variety of inert viscous materials can be used as the polymer, for example ethyl cellulose, ethylhydroxyethyl cellulose, wood rosin, epoxy resin, phenoxy resin, urethane resin, silicone resin, acrylic resin or a mixture thereof. The solvent such as texanol, terpineol and butyl carbitol acetate can be used to adjust the viscosity of the polymer paste to be preferable for applying on the ceramic green sheet.

The polymer can be 5 to 99 wt % in an embodiment, 10 to 70 wt % in another embodiment, 19 to 57 wt % in another embodiment based on the weight of the polymer paste. Especially when the polymer paste is non-photosensitive, the polymer paste can comprise 30 to 99 wt % in another embodiment, 35 to 75 wt % in another embodiment, 38 to 60 % in another embodiment based on the weight of the polymer paste.

The polymer paste can be negative photosensitive in another embodiment. In the event of the negative polymer paste which is photosensitive, the paste can further comprise a photopolymerization initiator and a photopolymerizable compound in another embodiment.

The photopolymerization initiator is a chemical compound that decomposes into free radicals when exposed to light. The photopolymerization initiator is thermally inactive at 185° C. or lower, but it generates free radicals when being exposed to an actinic ray. A compound that has two intra-molecular rings in the conjugated carboxylic ring system can be used as the photo-polymerization initiator, for example ethyl 4-dimethyl aminobenzoate (EDAB), diethylthioxanthone (DETX), and 2-Methyl-1[4-(methylthio)phenyl]-2-morpholinopropan-1-one. The photopolymerization initiator can be 0.1 to 8 wt % based on the weight of the polymer paste.

The photopolymerizable compound is a molecule that may chemically bind to other molecules to form a polymer. The photopolymerizable compound can be an organic monomer, an organic oligomer or an organic polymer. The photopolymerizable compound can include ethylenically unsaturated compounds having at least one polymerizable ethylene group. Examples of the photopolymerizable compound are ethoxylated (3) trimethylolpropane triacrylate, and dipentaerythritol penteacrylate. The photo-polymerization compound can be 5 to 40 wt % based on the weight of the polymer paste.

### EXAMPLES

Examples of the ceramic electronic component are described herein below. Weight percent (wt %) is based on the weight of the polymer paste, unless especially mentioned.

### Example 1

The polymer paste was prepared by mixing 58.5 wt % of butyl carbitol acetate as a solvent and 41.5 wt % of acrylic resin as a polymer at 100° C. in a stainless steel jar until the resin dissolved in the solvent. The polymer paste was not photosensitive.

This polymer paste had viscosity of 5 Pa·s at 25° C. measured by using a viscosimeter DV-I™ Prime HAT from Brookfield Co., Ltd. using a spindle #14 at 10 rpm at room temperature.

A polymer layer was formed by screen printing the polymer paste on a LTCC green sheet (70 mm long and 52 mm wide). The polymer layer was 50 mm long, 50 mm wide and 2.5 μm thick. The polymer layer was dried at 130° C. for 10 minutes.

The thick-film layer was formed by screen printing the negative photosensitive paste (Fodel® from E. I. du Pont de Nemours and Company) in size of 50 mm long, 50 mm wide and 9.5 μm thick on the polymer layer. Fodel® contained a silver powder to form an electrode circuit.

The thick-film layer was exposed to UV light of 365 nm wave length by using a collimated UV radiation source (exposure: 150 mJ/cm²) through a photomask having an L-shape line pattern. The L-shape line pattern of the photomask had 20 μm of line width, and 20 μm of space width between the lines. The target line width of the thick-film layer pattern after development was 20 μm which was same as the mask pattern.

The exposed thick-film layer was placed on a conveyor going in a spray developing device filled with 0.4% sodium carbonate aqueous solution which was kept at a temperature of 25° C. and sprayed for 15 seconds at 0.2 MPa. The unexposed thick-film layer was washed off to get the exposed thick-film layer which was L-shaped.

### Example 2

The polymer layer and the L-shape line pattern of the thick-film layer were made by the same method and same materials in Example 1 except for forming a negative photosensitive polymer layer.

The polymer paste which was negative photosensitive was prepared by mixing butyl carbitol acetate and acrylic resin as in Example 1 and further adding a photopolymerization initiator, a photopolymerizable compound and an additive. Acrylic resin was 23.3 wt %, butyl carbitol acetate was 41.1 wt %, the photopolymerization initiator was 5.2 wt %, the photopolymerizable monomer was 28 wt %, and the additive was 2.4 wt % based on the weight of the polymer paste.

The polymer paste which was photosensitive had viscosity of 5 Pa·s at 25° C. measured by the same method in Example 1.

The making process was carried out under yellow light.

The polymer layer was exposed to the UV light not independently but at the same time of the thick-film layer. The polymer layer and the thick-film layer were once exposed to the light simultaneously.

### Example 3

The polymer layer and the L-shape line pattern of the thick-film layer were made by the same method and the same materials as in Example 2 except that the photosensitive polymer layer and the thick-film layer was independently exposed to the UV light.

The photosensitive polymer layer on the LTCC green sheet was entirely exposed to the UV light without a photomask. The thick-film layer was formed on the exposed polymer layer.

### Comparative Example 1

The L-shaped pattern of the thick-film layer was formed in the same manner as Example 1 except for not forming the polymer layer. The thick-film layer was formed directly on the LTCC sheet.

### RESULT

The L-shaped pattern was sufficiently formed with less residue in Example 1 to 3 where the polymer layer was formed between the LTCC green sheet and the thick-film layer as shown in FIG. 3. to FIG. 5. The L-shaped pattern was formed with some residue in Comparative (Com.) Example 1 where the polymer layer was not formed, as shown in FIG. 6,

The line width of each L-shaped pattern was measured by a microscope having a measurement system CP30. The value of the line width was the average of ten points measurement. The line width difference from the target which was the photomask line pattern was expressed by the equation: Line difference (μm)=measured line width (μm)−target line width (20 μm).

As a result, the line width difference from the target got smaller when the polymer layer was photosensitive and further smaller when the photosensitive polymer layer was exposed independently as shown in Table 1.

TABLE 1

| | Example 1 | Example 2 | Example 3 |
|---|---|---|---|
| Polymer layer | Non- | Photosensitive | Photosensitive |
| | photosensitive | | |
| Exposure of | No | Simultaneously** | Independently*** |
| polymer layer | | | |
| Line width | 29.7 μm | 26.3 μm | 25.6 μm |
| (difference*) | (+9.7 μm) | (+6.3 μm) | (+5.6 μm) |

*Shown as difference from the target line width of 20 μm.
**The polymer layer and the thick-film layer were exposed simultaneously.
***The polymer layer and the thick-film layer was exposed independently.

1. A method of manufacturing a ceramic electronic component, comprising the steps of:
(i) forming a polymer layer on at least one side of a ceramic green sheet;
(ii) forming a thick-film layer by applying a photosensitive paste on the polymer layer;
(iii) exposing the thick-film layer to light;
(iv) developing the thick-film layer; and
(v) heating the ceramic green sheet and the thick-film layer.

2. The method of claim 1, wherein the thickness of the polymer layer is 0.1 to 100 μm.

3. The method of claim 1, wherein the polymer layer is formed by applying a polymer paste or a polymer film.

4. The method of claim 1, wherein the polymer layer is photosensitive.

5. The method of claim 4, wherein the method further comprises a step of (i-a) exposing the polymer layer to light between the step (i) of forming an polymer layer and the step (ii) of forming the thick-film layer.

6. The method of claim 1, wherein the method further comprises a step of (iv-a) laminating at least two ceramic green sheets on the developed thick-film layer between the step (iv) of developing the thick film layer and the step (v) of heating the ceramic green sheet and the thick-film layer.

7. The method of claim 1, wherein the photosensitive paste to form the thick-film layer comprises a functional inorganic powder selected from the group consisting of a metal powder, a metal oxide powder, and a glass powder.

8. A ceramic green sheet, wherein a polymer layer is formed on at least one side of the ceramic green sheet.
